(19) United States
(12) Patent Application Publication
(10) Pub. No.: US 2025/0266851 A1
(43) Pub. Date: Aug. 21, 2025

(54) ELECTRONIC DEVICE INCLUDING ANTENNAS AND ANTENNA TUNING METHOD

(71) Applicant: SAMSUNG ELECTRONICS CO., LTD., Suwon-si (KR)

(72) Inventor: Sunah Park, Suwon-si (KR)

(73) Assignee: SAMSUNG ELECTRONICS CO., LTD., Suwon-si (KR)

(21) Appl. No.: 19/039,247

(22) Filed: Jan. 28, 2025

(30) Foreign Application Priority Data
Feb. 15, 2024 (KR) 10-2024-0022053

(51) Int. Cl. H04B 1/00; H01Q 5/314; H03J 3/20

(52) U.S. Cl. CPC H04B 1/0053; H01Q 5/314; H03J 3/20

(57) ABSTRACT

An electronic device includes an antenna configured to transmit and receive signals within a plurality of frequency bands, a RFIC configured to transmit the signals within the plurality of frequency bands to the antenna, a coupler configured to transmit at least a portion of signals reflected from the antenna to the RFIC, a tuner connected to the antenna and the coupler, and a processor connected to the RFIC and the tuner, the processor configured to obtain a third reflection coefficient at a first receiving frequency based on a first reflection coefficient at a first transmission frequency and a second reflection coefficient at a second transmission frequency that is greater than the first transmission frequency, determine, based on the third reflection coefficient, a first receiving tuning code for performing impedance matching to the antenna, and control impedance of the antenna with the tuner based on the first receiving tuning code.

### CROSS-REFERENCE TO RELATED APPLICATION(S)

This application is based on and claims priority under 35 USC § 119 to Korean Patent Application No. 10-2024-0022053, filed on Feb. 15, 2024, in the Korean Intellectual Property Office, the disclosure of which is herein incorporated by reference in its entirety.

### BACKGROUND

Example embodiments of the disclosure relate to an electronic device including at least one antenna and an antenna tuning method.

With the advancement of mobile communication technology, the adoption of electronic devices with antennas, such as smartphones and wearable devices, has become widespread. Such electronic devices may transmit and/or receive various types of data (for example, messages, photos, videos, music files, and/or games) through antennas.

In an electronic device, antenna performance affects the transmission efficiency of a wireless signal. The antenna performance may dynamically vary depending on an environment in which an electronic device, such as a terminal, is used. For example, in a terminal to which a metal case is applied, impedance mismatch of an antenna may occur due to a change in external environment such as connection of a hand grip, universal serial bus (USB) device, or an earphone jack. As a result, a resonant frequency of the antenna may change, which may reduce the efficiency of an antenna output.

Accordingly, antenna tuning, in which antenna impedance is measured in real time to compensate for impedance mismatch and resonant frequency, may be used to improve antenna performance.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an electronic device capable of performing antenna tuning for a receiving frequency using a reflection coefficient measured at a transmit frequency.

Additional aspects will be set forth in part in the description which follows and, in part, will be apparent from the description, or may be learned by practice of the presented embodiments.

According to an aspect of an example embodiment, an electronic device may include an antenna configured to transmit and receive signals within a plurality of frequency bands, a radio-frequency integrated circuit (RFIC) configured to transmit the signals within the plurality of frequency bands to the antenna, a coupler configured to transmit at least a portion of signals reflected from the antenna to the RFIC, a tuner connected to the antenna and the coupler, and a processor connected to the RFIC and the tuner, where the processor is configured to obtain a third reflection coefficient at a first receiving frequency based on a first reflection coefficient at a first transmission frequency and a second reflection coefficient at a second transmission frequency that is greater than the first transmission frequency, determine, based on the third reflection coefficient, a first receiving tuning code for performing impedance matching to the antenna, and control impedance of the antenna with the tuner based on the first receiving tuning code.

According to an aspect of an example embodiment, an antenna tuning method may include determining a first reflection coefficient at a first transmission frequency and a second reflection coefficient at a second transmission frequency that is greater than the first transmission frequency, obtaining a third reflection coefficient at a first receiving frequency that is different from the first transmission frequency and the second transmission frequency, based on the first reflection coefficient and the second reflection coefficient, determining, based on the third reflection coefficient, a first receiving tuning code for performing impedance matching to the antenna, and controlling, with a tuner, impedance of an antenna based on the first receiving tuning code.

According to an aspect of an example embodiment, a wireless communication device configured to transmit and receive signals within a plurality of frequency bands may include an antenna, an RFIC configured to transmit a signal within a predetermined frequency band to the antenna, a coupler configured to transmit at least a portion of signals reflected from the antenna to the RFIC, a tuner connected to the antenna and the coupler, and a processor connected to the RFIC and the tuner, where the processor is configured to obtain a third reflection coefficient at a third frequency band between a first frequency band and a second frequency band that is greater than the first frequency band, based on a first reflection coefficient at a first transmission frequency and a second reflection coefficient at a second transmission frequency, determine a first receiving tuning code for performing impedance matching to the antenna based on the third reflection coefficient, and control impedance of the antenna with the tuner based on the first receiving tuning code.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a block diagram of an electronic device according to one or more embodiments;

FIG. 2 is a circuit diagram illustrating a configuration of a coupler and a tuner according to one or more embodiments;

FIG. 3A is a diagram illustrating a first transmission frequency, a second transmission frequency, and a first receiving frequency belonging to different frequency bands according to one or more embodiments;

FIG. 3B is a diagram illustrating a first transmission frequency and a second transmission frequency belonging to the same frequency band according to one or more embodiments;

FIG. 4A is a graph illustrating a first reflection coefficient in a first frequency band according to one or more embodiments;

FIG. 4B is a graph illustrating a second reflection coefficient in a second frequency band according to one or more embodiments;

FIG. 4C is a graph illustrating a third reflection coefficient in a third frequency band determined based on the first reflection coefficient and the second reflection coefficient according to one or more embodiments;

FIG. 5A is a diagram illustrating a configuration to determine an angle of the third reflection coefficient on a complex plane according to one or more embodiments;

FIG. 5B is a diagram illustrating a configuration to determine a magnitude of the third reflection coefficient on the complex plane according to one or more embodiments;

FIG. 6 is a flowchart illustrating a method of tuning an antenna according to one or more embodiments;

FIG. 7 is a flowchart illustrating a method of determining a first reflection coefficient according to one or more embodiments;

FIG. 8A is a flowchart illustrating a method of determining the angle of the third reflection coefficient on the complex plane according to one or more embodiments;

FIG. 8B is a flowchart illustrating a method of determining the magnitude of the third reflection coefficient on the complex plane according to one or more embodiments;

FIG. 9 is a block diagram illustrating an electronic device according to one or more embodiments;

FIG. 10 is a block diagram illustrating an Internet of Things (IoT) device including an electronic device according to one or more embodiments; and

FIG. 11 is a block diagram illustrating a mobile terminal to which an electronic device according to one or more embodiments is applied.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

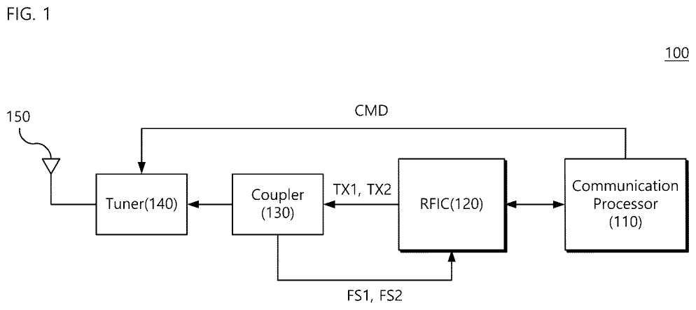

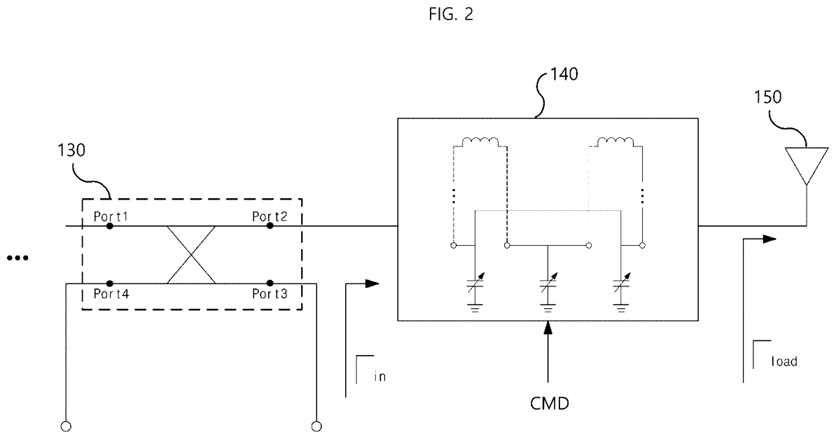

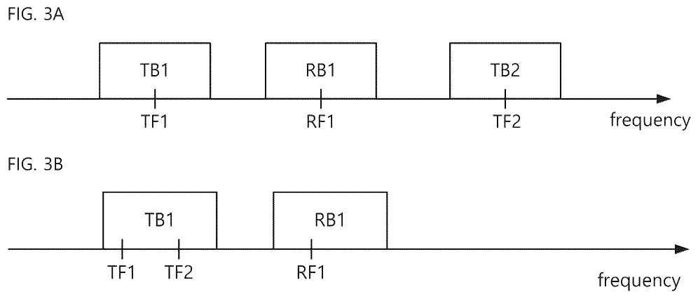

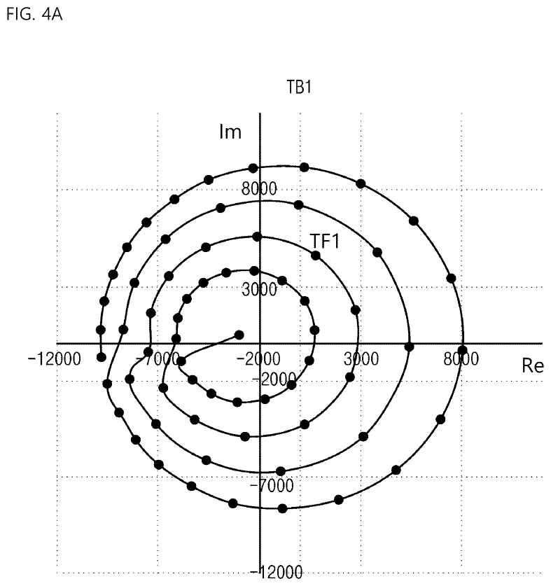

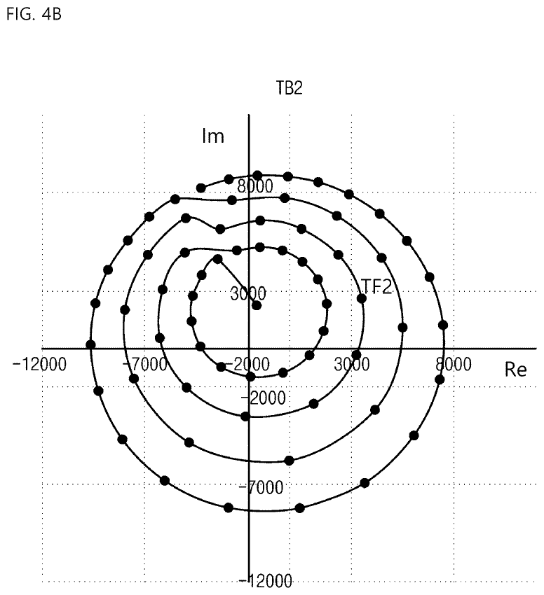

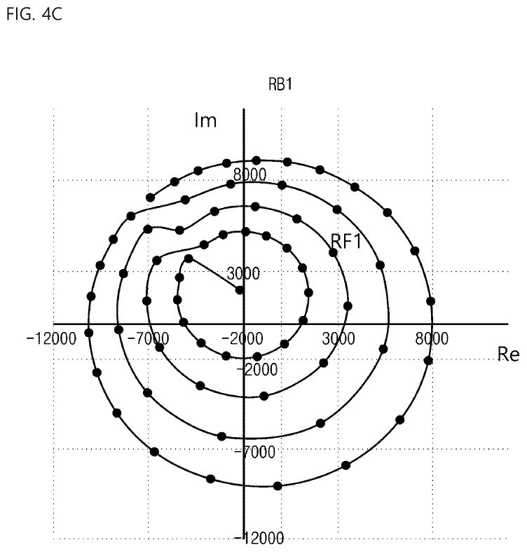

FIG. 1 is a block diagram of an electronic device according to one or more embodiments. FIG. 2 is a circuit diagram illustrating a configuration of a coupler and a tuner according to one or more embodiments. FIG. 3A is a diagram illustrating a first transmission frequency, a second transmission frequency, and a first receiving frequency belonging to different frequency bands according to one or more embodiments. FIG. 3B is a diagram illustrating a first transmission frequency and a second transmission frequency belonging to the same frequency band according to one or more embodiments. FIG. 4A is a graph illustrating a first reflection coefficient in a first frequency band according to one or more embodiments. FIG. 4B is a graph illustrating a second reflection coefficient in a second frequency band according to one or more embodiments. FIG. 4C is a graph illustrating a third reflection coefficient in a third frequency band calculated based on the first reflection coefficient and the second reflection coefficient according to one or more embodiments.

Referring to FIG. 1, an electronic device 100 according to one or more embodiments may include a communication processor 110, a radio-frequency integrated circuit (RFIC) 120, a coupler 130, and a tuner 140.

The electronic device 100 according to one or more embodiments may be various forms of devices. The electronic device 100 may include, for example, a mobile communication device such as a smartphone, a computer device, a portable multimedia device, a portable medical device, a camera, or a wearable device. However, the electronic device 100 according to one or more embodiments is not limited to the above-mentioned devices.

The electronic device 100 may include an antenna 150 that transmits and receives a radio-frequency (RF) signal including signals corresponding to a plurality of frequencies. Therefore, the electronic device 100 may be referred to as an antenna device, a wireless communication device, or a wireless transceiver that includes an antenna 150.

The electronic device 100 according to one or more embodiments may include an RFIC 120 that transmits the RF signal to the antenna 150. The electronic device 100 may include the RFIC 120 that transmits signals in a plurality of frequency bands, transmitted through the antenna 150, to the antenna 150.

For example, the RFIC 120 may convert a baseband signal into an RF signal or convert an RF signal into a baseband signal.

For example, at the time of reception, the RFIC 120 may convert an RF signal, received through an antenna 150, into a baseband signal such that the RF signal may be processed by the communication processor 110.

For example, at the time of transmission, the RFIC 120 may convert a baseband signal, generated by the communication processor 110, into an RF signal of approximately 700 MHz to approximately 3 GHz used for a first network (for example, a legacy network).

For example, at the time of transmission, the RFIC 120 may convert a baseband signal, generated by the communication processor 110, into an RF signal of Sub6 band (approximately 6 GHz or lower) used for a second network (for example, a 5th generation (5G) network).

For example, at the time of transmission, the RFIC 120 may convert a baseband signal, generated by the communication processor 110, into an RF signal in 5G Above5 band (for example, approximately 6 GHz to approximately 60 GHz) used for a third network (for example, a 5G network).

According to one or more embodiments, the RFIC 120 may transmit a first transmit signal TX1 and/or a second transmit signal TX2, corresponding to different frequencies, to the antenna 150.

The electronic device 100 may include a coupler 130 connected to the RFIC 120. For example, the electronic device 100 may include a coupler 130 transmitting a signal from the RFIC 120 to the antenna 150 or transmitting a signal, reflected from the antenna 150, to the RFIC 120.

Referring to FIG. 2, the coupler 130 may be implemented as a bidirectional coupler. For example, the coupler 130 may be implemented as a bidirectional coupler including a first port port1 to a fourth port port4.

According to one or more embodiments, the coupler 130 may output a signal, input through the first port port1, through the third port port3. Thus, the coupler 130 may transmit a signal, output from the RFIC 120, to the antenna 150 through the tuner 140.

According to one or more embodiments, the coupler 130 may output a signal, input through the second port port2, through the fourth port port4. Thus, the coupler 130 may transmit a signal, reflected from the antenna 150, to the RFIC 120. The signals, transmitted to the RFIC 120 through the coupler 130, may be referred to as feedback signals FS1 and FS2.

The electronic device 100 may include a tuner 140 connected to the coupler 130 and the antenna 150.

The tuner 140 may dynamically adjust an internal impedance under the control of the communication processor 110 to significantly reduce the signal reflected from the antenna 150.

For example, the tuner 140 may include an impedance tuner (or an impedance matching circuit and/or an aperture tuner). The aperture tuner may be formed as a portion of the antenna 150.

The electronic device 100 may include a communication processor 110 electrically connected to the tuner 140 and the RFIC 120. The communication processor 110 may refer to a specialized processor or a generalized processor capable of executing instructions to perform the functions described herein as will be understood by one of ordinary skill in the art from the disclosure herein.

The communication processor 110 may execute, for example, software (or program) to control at least one other component (for example, the RFIC 120 or the tuner 140) of the electronic device 100 and perform various data processing or computation. The communication processor 110 may include a central processing unit (CPU) or a microprocessor and may control the overall operation of the electronic device 100. Therefore, it will be understood by one of ordinary skill in the art that an operation performed by the electronic device 100 (or the RFIC 120) is performed under the control of the communication processor 110.

According to one or more embodiments, the communication processor 110 may include an algorithm to control at least a portion of the RFIC 120 and the tuner 140. For example, the algorithm may be software code programmed in the communication processor 110. For example, the algorithm may be hard code, hard-coded inside the communication processor 110, but embodiments are not limited thereto

According to the algorithm, the communication processor 110 may perform impedance tuning (or impedance matching) for the antenna 150 using the tuner 140.

For example, the communication processor 110 may control the tuner 140 to control the impedance of the antenna 150 and/or an electrical path, connected to the antenna 150, to significantly reduce the signal reflected from the antenna 150.

According to one or more embodiments, the communication processor 110 may control the RFIC 120 to transmit the transmit signals TX1 and TX2 having a specified frequency to the antenna 150.

For example, referring to FIG. 3A and FIG. 3B, the communication processor 110 may control the RFIC 120 to transmit the first transmit signal TX1 having a first transmission frequency TF1 and the second transmit signal TX2 having a second transmission frequency TF2 to the antenna 150.

In addition, the communication processor 110 may determine a reflection coefficient at each of the transmission frequencies TF1 and TF2 based on the feedback signals FS1 and FS2 transmitted from the coupler 130 to the RFIC 120.

For example, when the communication processor 110 transmits the first transmit signal TX1 through the antenna 150, the communication processor 110 may determine a first reflection coefficient at the first transmission frequency TF1 based on the first transmit signal TX1 and the first feedback signal FS1 transmitted to the RFIC 120 through the coupler 130.

In addition, when transmitting the second transmit signal TX2 through the antenna 150, the communication processor 110 may determine a second reflection coefficient at the second transmission frequency TF2 based on the second transmit signal TX2 and the second feedback signal FS2 transmitted to the RFIC 120 through the coupler 130.

The communication processor 110 may determine the reflection coefficient at each of the transmission frequencies TF1 and TF2 using Equation (1).

$${Γ}_{load} ( {Γ}_{l} ) = \frac{{Γ}_{i n} - {S}_{11}}{{S}_{22} {Γ}_{i n} - ( {S}_{11} {S}_{22} - {S}_{12} {S}_{21} )} \qquad ( 1 )$$

In Equation (1), S₁₁, S₁₂, S₂₁, and S₂₂ may be referred to as s-parameters measured through ports of the tuner 140 when the RF signal is transmitted through the antenna 150. For example, S₁₁ may be referred to as an s-parameter representing a ratio of a voltage input to the first port port1 of the tuner 140 and a voltage output to the second port port2 of the tuner 140.

In addition, Γ_{load} may be referred to as a reflection coefficient viewed from the antenna 150, and Γᵢₙ may be referred to as a reflection coefficient viewed from the communication processor 110.

For example, when transmitting an RF signal through the antenna 150, the communication processor 110 may determine a reflection coefficient viewed from the communication processor 110 based on the s-parameters of the tuner 140.

In addition, the communication processor 110 may determine a reflection coefficient at a frequency of the received signal based on the reflection coefficient determined for the transmission frequencies TF1 and TF2 of the transmit signals TX1 and TX2.

For example, the communication processor 110 may obtain (or determine) the reflection coefficient at the frequency of the received signal based on the reflection coefficients determined for the transmission frequencies TF1 and TF2 of the transmit signals TX1 and TX2.

For example, the communication processor 110 may determine a third reflection coefficient at the first receiving frequency RF1 based on the first reflection coefficient at the first transmission frequency TF1 and the second reflection coefficient at the second transmission frequency TF2.

Referring to FIG. 3A, the first receiving frequency RF1 may have a value between the first transmission frequency TF1 and the second transmission frequency TF2.

According to one or more embodiments, the first transmission frequency TF1 may be included in a first frequency band TB1 and the second transmission frequency TF2 may be included in a second frequency band TB2 that is larger than the first frequency band TB1. In addition, the first receiving frequency RF1 may be included in a third frequency band RB1 between the first frequency band TB1 and the second frequency band TB2.

Referring to FIG. 3B, the first receiving frequency RF1 may have a value, greater than the first transmission frequency TF1 and the second transmission frequency TF2.

The first transmission frequency TF1 and the second transmission frequency TF2 may belong to the first frequency band TB1. In addition, the first receiving frequency RF1 may belong to the third frequency band RB1 that is larger than the first frequency band TB1.

However, the magnitudes of the first transmission frequency TF1, the second transmission frequency TF2, and the first receiving frequency RF1 and a size of a frequency band, to which each frequency belongs, are not limited to the above examples.

For ease of description, an example is provided in which the first transmission frequency TF1, the second transmission frequency TF2, and the first receiving frequency RF1 are the same as illustrated in FIG. 3A.

The first reflection coefficient, the second reflection coefficient, and the third reflection coefficient may each have the form of a complex number. Therefore, the first reflection coefficient, the second reflection coefficient, and the third reflection coefficient may each be represented on a complex plane.

The communication processor 110 may determine an angle per unit frequency on the complex plane using the first reflection coefficient and the second reflection coefficient. In addition, the communication processor 110 may obtain an angle of the third reflection coefficient on the complex plane based on the angle per unit frequency.

The communication processor 110 may determine the magnitude per unit frequency on the complex plane using the first reflection coefficient and the second reflection coefficient. In addition, the communication processor 110 may obtain the magnitude of the third reflection coefficient on the complex plane based on the magnitude per unit frequency.

Through the above-described configurations, the communication processor 110 may obtain the third reflection coefficient of the first receiving frequency RF1 from the first reflection coefficient and the second reflection coefficient.

Referring to FIG. 3A, the first transmission frequency TF1, the second transmission frequency TF2, and the first receiving frequency RF1 may be referred to as representative frequencies (or center frequencies) of the first frequency band TB1, the second frequency band TB2, and the third frequency band RB1, respectively.

The representative frequency may be a center frequency of a frequency range (for example, a first frequency band TB1) in which an impedance tuning value is relatively constant.

Therefore, referring to FIG. 4A to FIG. 4C, the communication processor 110 may obtain a reflection coefficient of a corresponding frequency in the third frequency band RB1 based on the reflection coefficients at different frequencies in the first frequency band TB1 and the second frequency band TB2.

In addition, the communication processor 110 may determine a first receiving tuning code based on the reflection coefficient at the first receiving frequency RF1 obtained using the reflection coefficients at the transmission frequencies TF1 and TF2.

For example, the communication processor 110 may determine the first receiving tuning code for performing impedance matching for the antenna 150 based on the reflection coefficient at the first receiving frequency RF1.

According to one or more embodiments, the communication processor 110 may store a look-up table including a plurality of tuning codes. Alternatively, the plurality of tuning codes may be pre-stored in a memory accessible by the communication processor 110.

For example, the look-up table may include a tuning value, for example, a tuning code, corresponding to various values of the reflection coefficient. The tuning code may be a setting code adjusting impedance setting of the antenna 150. The tuning code corresponding to values of the reflection coefficient measured under various impedance conditions at the representative frequency may be pre-determined and stored in the look-up table.

The communication processor 110 according to one or more embodiments may search the look-up table based on the third reflection coefficient. In addition, the communication processor 110 may select the first receiving tuning code corresponding to the third reflection coefficient from the look-up table.

According to one or more embodiments, the communication processor 110 may determine a first receiving tuning code, in which a transducer gain Gt is maximum, based on the following Equation (2).

$${G}_{t} = \frac{{\vert {S}_{21} \vert}^{2} ( 1 - {Γ}_{i n}^{2} ) ( 1 - {Γ}_{load}^{2} )}{{\vert 1 - {Γ}_{s} {Γ}_{i n} \vert}^{2} {\vert 1 - {Γ}_{out} {Γ}_{load} \vert}^{2}} \qquad ( 2 )$$

In Equation (2), Γₛ may be referred to as a reflection coefficient viewed from the tuner 140. For example, Γₛ may be referred to as “0” when the impedance of the antenna 150 is matched.

According to one or more embodiments, the communication processor 110 may determine a first receiving tuning code, in which a transducer gain Gt is maximum, by substituting s-parameters corresponding to a plurality of tuning codes stored in the look-up table into Equation (2).

For example, the communication processor 110 may determine the first receiving tuning code, in which a transducer gain Gt of an electrical path (or the tuner 140) connected to the antenna 150 is maximum, based on the third reflection coefficient at the first receiving frequency RF1.

Referring to the above-described configurations, the communication processor 110 may determine the first receiving tuning code, among the plurality of tuning codes stored in the look-up table, based on the third reflection coefficient at the first receiving frequency RF1.

In addition, the communication processor 110 may control the tuner 140 based on the first receiving tuning code. For example, the communication processor 110 may control the impedance of the antenna 150 through the tuner 140 based on the first receiving tuning code.

Referring to FIG. 2, the tuner 140 according to one or more embodiments may include at least one capacitor and at least one switch. In addition, the tuner 140 according to one or more embodiments may be connected to an inductor externally provided.

For example, the communication processor 110 may control a voltage, applied to the tuner 140, to adjust at least a portion of the magnitude and phase of the impedance of the antenna 150 based on the first receiving tuning code.

For example, the communication processor 110 may generate a control signal CMD corresponding to the first receiving tuning code. In addition, the communication processor 110 may provide the control signal CMD to the tuner 140.

Thus, the communication processor 110 may control a capacitor and/or a switch inside the tuner 140 to compensate for impedance mismatch through the control signal CMD.

According to one or more embodiments, the communication processor 110 may store the first transmission tuning code in a storage space (for example, a look-up table) inside the electronic device 100 (or the communication processor 110).

According to one or more embodiments, the communication processor 110 may determine transmission tuning code based on a reflection coefficient at each of the transmission frequency TF1 and TF2 when the communication processor 110 transmits the first transmit signal TX1 or the second transmit signal TX2 through the antenna 150.

For example, the communication processor 110 may determine transmission tuning code, in which the transducer gain Gt of the electrical path (or the tuner 140) connected to the antenna 150 is maximum, based on the reflection coefficient at each of the transmission frequencies TF1 and TF2.

For example, the communication processor 110 may determine transmission tuning code in which the transducer gain Gt of the electrical path (or the tuner 140) connected to the antenna 150 is maximum, among the plurality of tuning codes stored in the look-up table, based on the reflection coefficient at each of the transmission frequencies TF1 and TF2.

In addition, the communication processor 110 may control the tuner 140 based on the determined transmission tuning code. Thus, the communication processor 110 may improve the transmission performance of the antenna 150.

Referring to the above-described configurations, the communication processor 110 according to one or more embodiments may obtain the reflection coefficient for the receiving frequency based on the reflection coefficients of different transmission frequencies TF1 and TF2.

In addition, when receiving an RF signal through the antenna 150, the communication processor 110 may control the impedance of the antenna 150 based on the reflection coefficient for the receiving frequency or the receiving tuning code determined based on the reflection coefficient for the receiving frequency.

Thus, the electronic device 100 according to one or more embodiments may improve the reception performance of the antenna 150 using the reflection coefficients measured at the transmission frequency.

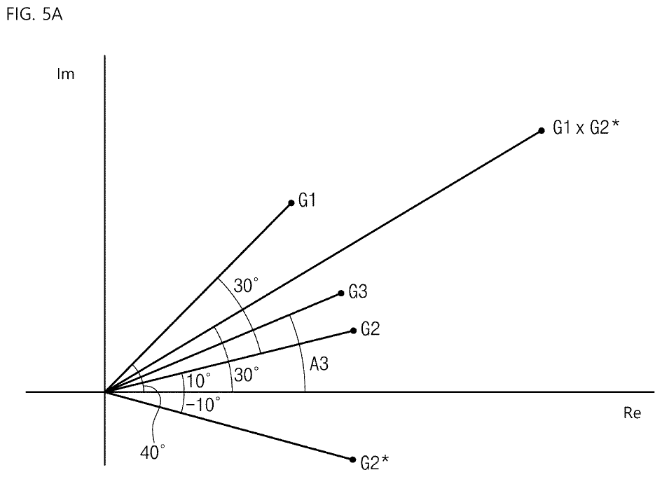

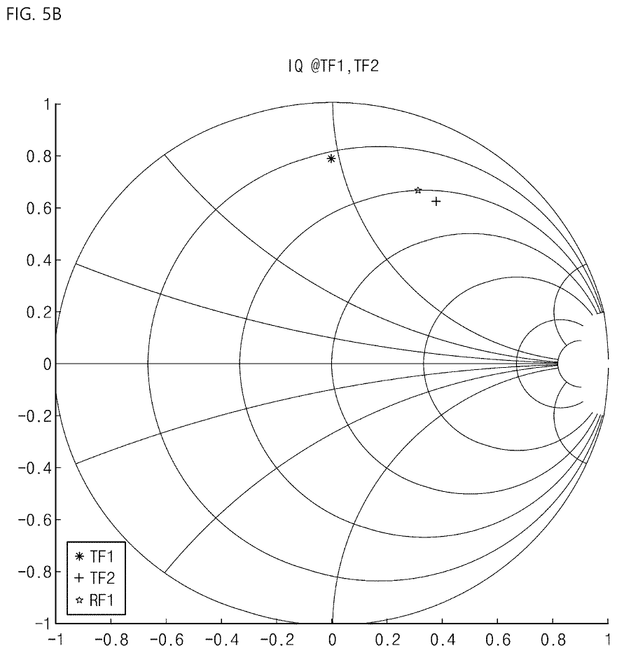

FIG. 5A is a diagram illustrating a configuration to determine an angle of the third reflection coefficient on a complex plane according to one or more embodiments. FIG. 5B is a diagram illustrating a configuration to determine a magnitude of the third reflection coefficient on the complex plane according to one or more embodiments.

Referring to FIG. 5A and FIG. 5B, a communication processor 110 according to one or more embodiments may determine a third reflection coefficient G3 based on a first reflection coefficient G1 and a second reflection coefficient G2 represented on a complex plane.

Referring to FIG. 5A, the communication processor 110 according to one or more embodiments may determine a third angle A3 of the third reflection coefficient G3 with respect to a real axis Re based on an angle that each of the first reflection coefficient G1 and the second reflection coefficient G2 has with respect to the real axis Re on a complex plane.

For example, the communication processor 110 may determine the third angle A3 of the third reflection coefficient G3 with respect to the real axis Re based on an angle between the first reflection coefficient G1 and the second reflection coefficient G2 on the complex plane.

The communication processor 110 may determine the angle between the first reflection coefficient G1 at a first transmission frequency TF1 and the second reflection coefficient G2 at a second transmission frequency TF2.

According to one or more embodiments, the communication processor 110 may multiply a conjugate complex number G2* of the second reflection coefficient G2 by the first reflection coefficient G1 to determine the angle between the first reflection coefficient G1 and the second reflection coefficient G2.

For example, when the first reflection coefficient G1 has an angle of 40 degrees with respect to the real axis Re and the second reflection coefficient G2 has an angle of 10 degrees with respect to the real axis Re, the communication processor 110 may multiply the conjugate complex number G2* of the second reflection coefficient G2 by the first reflection coefficient G1 to determine a 30-degree angle between the first reflection coefficient G1 and the second reflection coefficient G2.

According to one or more embodiments, the communication processor 110 may subtract the angle of the second reflection coefficient G2 with respect to the real axis Re from the angle of the first reflection coefficient G1 with respect to the real axis Re to determine the angle between the first reflection coefficient G1 and the second reflection coefficient G2.

For example, the communication processor 110 may subtract a 10-degree angle of the second reflection coefficient G2 with respect to the real axis Re from a 40-degree angle of the first reflection coefficient G1 with respect to the real axis Re to determine a 30-degree angle between the first reflection coefficient G1 and the second reflection coefficient G2.

In addition, the communication processor 110 may determine an angle per unit frequency based on the angle between the first reflection coefficient G1 and the second reflection coefficient G2.

For example, the communication processor 110 may divide the angle between the first reflection coefficient G1 and the second reflection coefficient G2 by a frequency difference between the first transmission frequency TF1 and the second transmission frequency TF2 to determine the angle per unit frequency.

For example, when the frequency difference between the first transmission frequency TF1 and the second transmission frequency TF2 is 61 MHz, the communication processor 110 may divide the angle between the first reflection coefficient G1 and the second reflection coefficient G2 by 61 MHz to obtain an angle of 0.5357 degrees per 1 MHz.

Thus, the communication processor 110 may determine that the reflection coefficient rotates by 0.5357 degrees on the complex plane when the frequency of the signal transmitted and received through the antenna 150 changes by 1 MHz, a unit frequency.

In addition, the communication processor 110 may determine an angle that the third reflection coefficient G3 at the first receiving frequency RF1 has with respect to the real axis Re on the complex plane, based on the angle per unit frequency.

For example, the communication processor 110 may multiply the frequency difference between the first receiving frequency RF1 and the first transmission frequency TF1 or the second transmission frequency TF2 by the angle per unit frequency to determine the angle that the third reflection coefficient G3 at the first receiving frequency RF1 has with respect to the real axis Re on the complex plane.

For example, when the first transmission frequency TF1 is 836500 KHz and the first receiving frequency RF1 is 881500 KHz, the frequency difference between the two frequencies is 45000 KHz. Therefore, the communication processor 110 may multiply the angle per unit frequency by 45 MHz to determine −24.1065 degrees, an angle difference between the first reflection coefficient G1 and the third reflection coefficient G3.

For example, the communication processor 110 may determine that the third reflection coefficient G3 at the first receiving frequency RF1 has a third angle A3 of 15.8935 degrees with respect to the real axis Re on the complex plane.

Thus, the communication processor 110 may determine the third angle A3 that the third reflection coefficient G3 has with respect to the real axis Re on the complex plane.

Referring to FIG. 5B, the communication processor 110 according to one or more embodiments may determine a third magnitude of the third reflection coefficient G3 based on the magnitude of each of the first reflection coefficient G1 and the second reflection coefficient G2, represented on the complex plane.

For example, the communication processor 110 may divide a difference in magnitude between the first reflection coefficient G1 and the second reflection coefficient G2 on the complex plane by a frequency difference between the first transmission frequency TF1 and the second transmission frequency TF2 to determine the magnitude per unit frequency.

For example, when the first transmission frequency TF1 is 836500 KHz, the second transmission frequency TF2 is 897500 KHz, the first reflection coefficient G1 is 1592+12657i, and the second reflection coefficient G2 is 7690+8487i, the communication processor 110 may determine −21.3768, a magnitude per unit frequency.

In addition, the communication processor 110 may determine the third magnitude of the third reflection coefficient G3 based on the magnitude per unit frequency.

For example, the communication processor 110 may add the product of the frequency difference between the first transmission frequency TF1 and the first receiving frequency RF1 and the magnitude per unit frequency to the magnitude of the first reflection coefficient G1 to determine the third magnitude of the third reflection coefficient G3.

For example, the communication processor 110 may add −21.3768 to 12756.7281, the first magnitude of the first reflection coefficient G1, to determine 12735.3513, the third magnitude of the third reflection coefficient G3.

For example, the communication processor 110 may determine that the third reflection coefficient G3 has a magnitude of 12735.35131 on the complex plane.

In addition, the communication processor 110 may determine a location of the third reflection coefficient G3 on the complex plane based on the third angle and third magnitude of the third reflection coefficient G3 with respect to the real axis Re on the complex plane.

As described above, the communication processor 110 may obtain the third reflection coefficient G3 at the first receiving frequency RF1 based on the reflection coefficients G1 and G2 obtained for different transmission frequencies TF1 and TF2.

In addition, when receiving an RF signal through the antenna 150, the communication processor 110 may control the impedance of the antenna 150 through the tuner 140 based on the reflection coefficient at the receiving frequency or the receiving tuning code determined by the reflection coefficient at the receiving frequency.

As a result, the electronic device 100 according to one or more embodiments may improve the reception performance of the antenna 150 using the reflection coefficients measured at the transmission frequency.

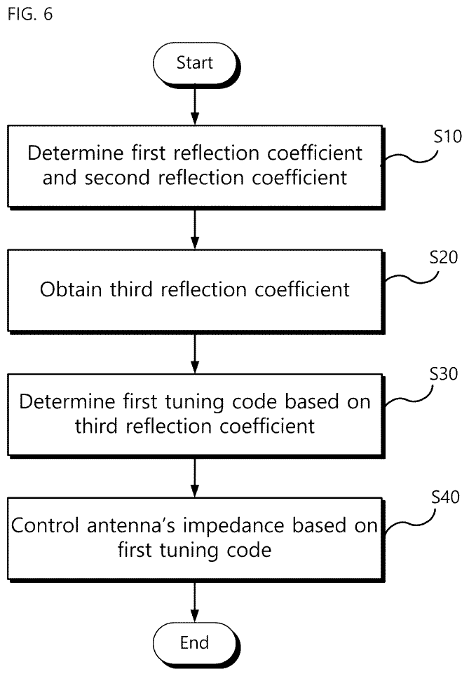

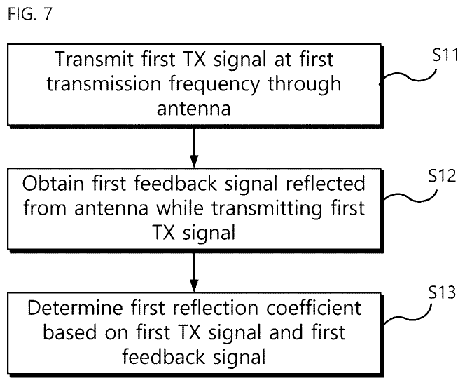

FIG. 6 is a flowchart illustrating a method of tuning an antenna according to one or more embodiments. FIG. 7 is a flowchart illustrating a method of determining a first reflection coefficient according to one or more embodiments. That is, FIG. 7 is a flowchart illustrating operations that are performed in operation S10 of FIG. 6.

Referring to FIG. 6, the communication processor 110 (or the electronic device 100) according to one or more embodiments may obtain a reflection coefficient at a receiving frequency based on reflection coefficients obtained for different transmission frequencies.

In addition, the communication processor 110 may control the impedance of the antenna 150 based on the reflection coefficient at the receiving frequency.

In operation S10, the communication processor 110 according to one or more embodiments may determine the first reflection coefficient G1 and the second reflection coefficient G2. For example, the communication processor 110 may determine the first reflection coefficient G1 at the first transmission frequency TF1 and the second reflection coefficient G2 at the second transmission frequency TF2.

Referring to FIG. 7, in operation S11, the communication processor 110 may transmit the first transmit signal TX1 of the first transmission frequency TF1 through the antenna 150.

In operation S12, the communication processor 110 may obtain the first feedback signal FS1, reflected from the antenna 150, during transmission of the first transmit signal TX1.

For example, the communication processor 110 may obtain the first feedback signal FS1, reflected from the antenna 150, through the coupler 130 during transmission of the first transmit signal TX1 through the antenna 150.

In operation S13, the communication processor 110 may obtain the first reflection coefficient G1 based on the first transmit signal TX1 and the first feedback signal FS1.

In addition, when transmitting the second transmit signal TX2 of the second transmission frequency TF2, the communication processor 110 may determine the second reflection coefficient G2 at the second transmission frequency TF2 based on the second transmit signal TX2 and the second feedback signal FS2 reflected from the antenna 150 and transmitted to the RFIC 120 through the coupler 130.

It will be understood by one of ordinary skill in the art that the operation of the communication processor 110 obtaining the second reflection coefficient G2 may be substantially the same as the operation of the communication processor 110 obtaining the first reflection coefficient G1 described with respect to FIG. 7.

In operation S20, the communication processor 110 according to one or more embodiments may obtain the third reflection coefficient G3. For example, the communication processor 110 may obtain the third reflection coefficient G3 at the first receiving frequency RF1 based on the first reflection coefficient G1 and the second reflection coefficient G2.

For example, the communication processor 110 may determine the angle per unit frequency on the complex plane using the first reflection coefficient G1 and the second reflection coefficient G2. In addition, the communication processor 110 may obtain the angle of the third reflection coefficient G3 on the complex plane based on the angle per unit frequency.

In addition, the communication processor 110 may determine the magnitude per unit frequency on the complex plane using the first reflection coefficient G1 and the second reflection coefficient G2. In addition, the communication processor 110 may obtain the third magnitude G3 of the third reflection coefficient G3 on the complex plane based on the magnitude per unit frequency.

Thus, the communication processor 110 may obtain the third reflection coefficient G3 at the first receiving frequency RF1 from the first reflection coefficient G1 and the second reflection coefficient G2 at different transmission frequencies TF1 and TF2.

In operation S30, the communication processor 110 according to one or more embodiments may determine the first receiving tuning code based on the third reflection coefficient G3.

For example, the communication processor 110 may determine the first receiving tuning code to perform impedance matching for the antenna 150, among the plurality of tuning codes stored in the lookup table, based on the third reflection coefficient.

For example, the communication processor 110 may determine the first receiving tuning code to control the tuner 140 so that the conversion gain Gt of the electrical path (or the tuner 140) connected to the antenna 150 is maximum, using the third reflection coefficient and a pre-stored equation (for example, Equation (2)).

In operation S40, the communication processor 110 according to one or more embodiments may control the impedance of the antenna 150 based on the first receiving tuning code.

For example, the communication processor 110 may control a voltage applied to the tuner 140 to adjust at least a portion of the magnitude and phase of the impedance of the antenna 150 based on the first receiving tuning code.

For example, the communication processor 110 may generate a control signal CMD corresponding to the first receiving tuning code. In addition, the communication processor 110 may provide the control signal CMD to the tuner 140.

Thus, the communication processor 110 may control a capacitor and/or a switch inside the tuner 140 through the control signal CMD to compensate for impedance mismatch.

As described above, the communication processor 110 according to one or more embodiments may obtain the third reflection coefficient G3 for the first receiving frequency RF1 based on the reflection coefficients G1 and G2 of different transmission frequencies TF1 and TF2.

Furthermore, when receiving a signal at the first receiving frequency RF1 through the antenna 150, the communication processor 110 may control the impedance of the antenna 150 based on the third reflection coefficient G3 or the first receiving tuning code determined by the third reflection coefficient G3.

As a result, the electronic device 100 according to one or more embodiments may improve the reception performance of the antenna 150 using the reflection coefficients measured at different transmission frequencies.

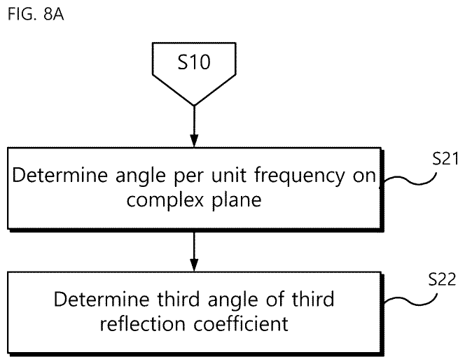

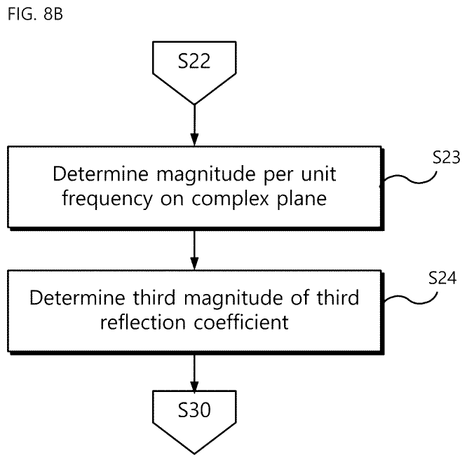

FIG. 8A is a flowchart illustrating a method of determining the angle of the third reflection coefficient on the complex plane according to one or more embodiments. FIG. 8B is a flowchart illustrating a method of determining the magnitude of the third reflection coefficient on the complex plane according to one or more embodiments.

Referring to FIGS. 8A and 8B, the communication processor 110 (or the electronic device 100) according to one or more embodiments may determine the third reflection coefficient G3 based on the first reflection coefficient G1 and the second reflection coefficient G2 represented on the complex plane.

Referring to FIG. 8A, the communication processor 110 according to one or more embodiments may determine the third angle A3 of the third reflection coefficient G3 with respect to the real axis Re based on an angle of each of the first reflection coefficient G1 and the second reflection coefficient G2 with respect to the real axis Re, represented on the complex plane. That is, the operations in FIG. 8A may be performed subsequent to operation S10 of FIG. 6 and may correspond to operation S20 of FIG. 6.

In operation S21, the communication processor 110 may determine an angle per unit frequency on the complex plane.

For example, the communication processor 110 may determine an angle between the first reflection coefficient G1 and the second reflection coefficient G2.

For example, the communication processor 110 may multiply a conjugate complex number G2* of the second reflection coefficient G2 by the first reflection coefficient G1 to determine the angle between the first reflection coefficient G1 and the second reflection coefficient G2.

For example, the communication processor 110 may subtract the angle of the second reflection coefficient G2 with respect to the real axis Re from the angle of the first reflection coefficient G1 with respect to the real axis Re to determine the angle between the first reflection coefficient G1 and the second reflection coefficient G2.

Furthermore, the communication processor 110 may determine an angle per unit frequency based on the angle between the first reflection coefficient G1 and the second reflection coefficient G2.

For example, the communication processor 110 may divide the angle between the first reflection coefficient G1 and the second reflection coefficient G2 by the frequency difference between the first transmission frequency TF1 and the second transmission frequency TF2 to determine the angle per unit frequency.

In operation S22, the communication processor 110 may determine the third angle A3 that the third reflection coefficient G3 has with respect to the real axis Re on the complex plane.

For example, the communication processor 110 may determine the angle that the third reflection coefficient G3 at the first receiving frequency RF1 has with respect to the real axis Re on the complex plane, based on the angle per unit frequency.

For example, the communication processor 110 may multiply the angle per unit frequency by the frequency difference between the first receiving frequency RF1 and the first transmission frequency TF1 or the second transmission frequency TF2 to determine the angle that the third reflection coefficient G3 at the first receiving frequency RF1 has with respect to the real axis Re on the complex plane.

Thus, the communication processor 110 may determine the third angle A3 that the third reflection coefficient G3 has with respect to the real axis Re on the complex plane.

Referring to FIG. 8B, the communication processor 110 according to one or more embodiments may determine the third magnitude G3 of the third reflection coefficient G3 based on the magnitude of each of the first reflection coefficient G1 and the second reflection coefficient G2. That is, the operations in FIG. 8A may be performed subsequent to operation S22 of FIG. 8A.

In operation S23, the communication processor 110 may determine the magnitude per unit frequency on the complex plane.

For example, the communication processor 110 may divide a difference in magnitude between the first reflection coefficient G1 and the second reflection coefficient G2 on the complex plane by a frequency difference between the first transmission frequency TF1 and the second transmission frequency TF2 to determine the magnitude per unit frequency.

In operation S24, the communication processor 110 may determine the third magnitude of the third reflection coefficient G3 based on the magnitude per unit frequency.

For example, the communication processor 110 may add the product of the magnitude per unit frequency and the frequency difference between the first transmission frequency TF1 and the first receiving frequency RF1 to the magnitude of the first reflection coefficient G1 to determine the third magnitude of the third reflection coefficient G3.

In addition, the communication processor 110 may determine a location of the third reflection coefficient G3 on the complex plane based on the third angle A3 and the third magnitude of the third reflection coefficient G3 with respect to the real axis Re on the complex plane.

As described above, the communication processor 110 may obtain the reflection coefficient G3 at the first receiving frequency RF1 based on the reflection coefficients G1 and G2 obtained at different transmission frequencies.

In addition, when receiving a signal at the first receiving frequency RF1 through the antenna 150, the communication processor 110 may control the impedance of the antenna 150 based on the third reflection coefficient G3 or the first receiving tuning code determined by the third reflection coefficient G3.

As a result, the electronic device 100 according to one or more embodiments may improve the reception performance of the antenna 150 using the reflection coefficients G1 and G2 measured at different transmission frequencies TF1 and TF2.

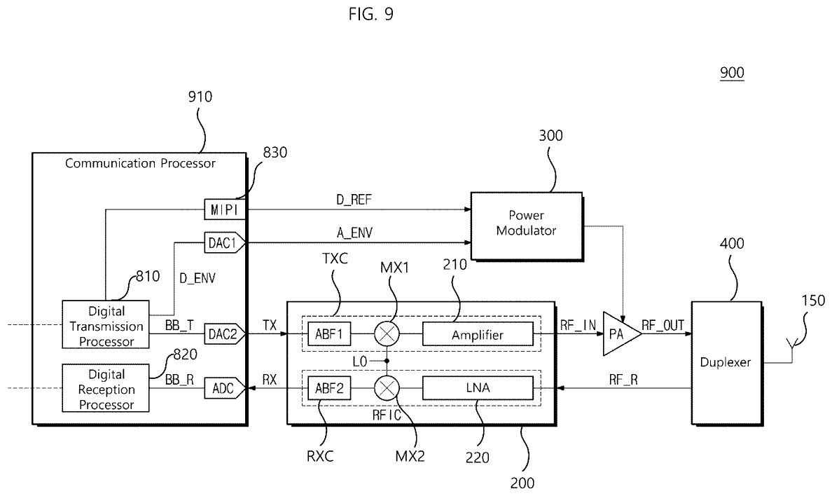

FIG. 9 is a block diagram illustrating an electronic device according to one or more embodiments.

Referring to FIG. 9, a wireless communication device 900 according to one or more embodiments may include a communication processor 910, an RFIC 200, a supply modulator 300, a duplexer 400, a power amplifier PA, and an antenna 150.

The wireless communication device 900 and a configuration thereof, illustrated in FIG. 9, may be understood as an example of the electronic device 100 and the configuration thereof illustrated in FIG. 1. Therefore, the same or substantially the same components will be denoted by the same reference numerals, and redundant descriptions may be omitted.

The communication processor 910 may process a baseband signal BB_T based on a predetermined communication scheme through a digital transmission processor 810 therein. In addition, the communication processor 910 may process a received baseband signal BB_R based on a predetermined communication scheme through a digital reception processor 820 therein.

For example, the communication processor 910 may process a signal to be transmitted or a received signal, based on a communication scheme such as orthogonal frequency division multiplexing (OFDM), orthogonal frequency division multiplexing access (OFDMA), wideband code multiple access (WCDMA), or high speed packet access+ (HSPA+). In addition, the communication processor 910 may process the baseband signal BB_T or BB_R based on various types of communication schemes (for example, various communication schemes to which a technique for modulating or demodulating an amplitude and a frequency of the baseband signal BB_T or BB_R is applied).

The communication processor 910 may extract an envelope of the baseband signal BB_T through the digital transmission processor 810 and generate a digital envelope signal D_ENV based on the extracted envelope. In addition, the communication processor 910 may generate an average power signal D_REF based on an average power tracking table stored in a memory. The extracted envelope may correspond to an amplitude component (for example, magnitudes of an I signal and a Q signal) of the baseband signal BB_T.

The communication processor 910 may perform digital-to-analog conversion on the baseband signal BB_T and the digital envelope signal D_ENV using a plurality of digital-to-analog converters DAC1 and DAC2 provided therein to generate a transmission signal TX and an analog envelope signal A_ENV, which are analog signals. For example, the average power signal D_REF output from the communication processor 910 may be a digital signal. Accordingly, the average power signal D_REF may be provided to the digital-to-analog converter provided within the supply modulator 300 through a mobile industry processor interface (MIPI) 830, and may be converted into an analog signal, such as a reference voltage signal, by the digital-to-analog converter provided within the supply modulator 300. For reference, the digital-to-analog converters DAC1 and DAC2 provided in the communication processor 910 may operate at a relatively high speed compared to the digital-to-analog converter provided in the supply modulator 300.

However, embodiments are not limited thereto, and the communication processor 910 may convert the average power signal D_REF into an analog signal and output the converted analog signal through the digital-to-analog converter provided therein. In one or more embodiments, the communication processor 910 may provide the average power signal, converted into the analog signal, to the supply modulator 300 as a reference voltage signal.

For ease of description, an example will be provided in which the communication processor 910 provides the average power signal D_REF to the digital-to-analog converter provided within the supply modulator 300 through the MIPI 830.

For reference, each of the transmission signal TX and the analog envelope signal A_ENV may be a differential signal including a positive signal and a negative signal.

In addition, the communication processor 910 may receive a receive signal RX, an analog signal, from the RFIC 200. In addition, the communication processor 910 may perform analog-to-digital conversion on the receive signal RX using the analog-to-digital converter ADC provided therein to extract the baseband signal BB_R, a digital signal. The receive signal RX may be a differential signal including a positive signal and a negative signal.

The RFIC 200 may perform frequency up-conversion on the transmit signal TX to generate an RF input signal RF_IN, or perform frequency down-conversion on the RF receive signal RF_R to generate a receive signal RX. For example, the RFIC 200 may include a transmit circuit TXC for frequency up-conversion, a receive circuit RXC for frequency down-conversion, and a local oscillator LO.

The transmit circuit TXC may include a first analog baseband filter ABF1, a first mixer MX1, and an amplifier 210. For example, the first analog baseband filter ABF1 may include a low-pass filter.

The first analog baseband filter ABF1 may filter the transmit signal TX received from the communication processor 910 and provide the filtered transmit signal to the first mixer MX1. In addition, the first mixer MX1 may perform frequency up-conversion to convert a frequency of the transmit signal TX from baseband into a high-frequency band using the frequency signal provided by the local oscillator LO. Through such frequency up-conversion, the transmit signal TX may be provided to the amplifier 210 as an RF input signal RF_IN, and the amplifier 210 may power-amplify the RF input signal RF_IN and provide the power-amplified RF input signal to the power amplifier PA.

The power amplifier PA may receive a power supply voltage (for example, a dynamically variable output voltage) from the supply modulator 300, and may amplify power of the RF input signal RF_IN based on the received power supply voltage to generate an RF output signal RF_OUT. In addition, the power amplifier PA may provide the generated RF output signal RF_OUT to the duplexer 400.

The receive circuit RXC may include a second analog baseband filter ABF2, a second mixer MX2, and a low-noise amplifier 220. For example, the second analog baseband filter ABF2 may include a low-pass filter.

The low-noise amplifier 220 may amplify the RF receive signal RF_R, received from the duplexer 400, and provide the amplified RF receive signal to the second mixer MX2. The second mixer MX2 may perform frequency down-conversion to convert a frequency of the receive signal RF_R from a high-frequency band to baseband using the frequency signal provided by the local oscillator LO. Through such frequency down-conversion, the RF receive signal RF_R may be provided to the second analog baseband filter ABF2 as a receive signal RX, and the second analog baseband filter ABF2 may filter the receive signal RX and provide the filtered receive signal to the communication processor 910.

For reference, the wireless communication device 900 may transmit a transmit signal through a plurality of frequency bands using carrier aggregation (CA). To this end, the wireless communication device 900 may include a plurality of power amplifiers that power-amplify a plurality of RF input signals RF_IN, respectively corresponding to a plurality of carriers. However, for ease of description, an example will be provided in which the power amplifier PA is provided in singular.

The supply modulator 300 may generate a modulated output voltage having a level dynamically varied based on the analog envelope signal A_ENV and the average power signal D_REF, and may provide the generated output voltage to the power amplifier PA as a power supply voltage.

For example, the supply modulator 300 may receive the average power signal D_REF and the analog envelope signal A_ENV from the communication processor 910. In addition, the supply modulator 300 may operate in envelope tracking (ET) mode or average power tracking (APT) mode based on the received average power signal D_REF and analog envelope signal A_ENV to generate a dynamically varied output voltage. In addition, the supply modulator 300 may supply the generated output voltage to the power amplifier PA as a power supply voltage.

For reference, when a power supply voltage having a fixed level is applied to the power amplifier PA, the power efficiency of the power amplifier PA may be degraded. Therefore, the supply modulator 300 may modulate an input voltage (for example, power supplied from a battery) based on at least one of the analog envelope signal A_ENV and the average power signal D_REF and provide the modulated voltage to the power amplifier PA as a power supply voltage to efficiently manage power of the power amplifier PA.

The duplexer 400 may be connected to the antenna 150 to separate a transmission frequency and a receiving frequency from each other. For example, the duplexer 400 may separate the RF output signal RF_OUT, received from the power amplifier PA, for each frequency band and provide the separated RF output signal to a corresponding antenna 150. In addition, the duplexer 400 may provide an external signal, received from the antenna 150, to the low-noise amplifier 220 of the receive circuit RXC of the RFIC 200. For example, the duplexer 400 may include a front end module with integrated duplexer (FEMiD).

For reference, the wireless communication device 900 may be provided with a switch structure for separating the transmission frequency and the receiving frequency from each other, rather than the duplexer 400. In addition, the wireless communication device 900 may have a structure including a duplexer 400 and a switch to separate the transmission frequency and the receiving frequency from each other. For ease of description, an example will be provided in which the wireless communication device 900 is provided with the duplexer 400 that may separate the transmission frequency and the receiving frequency from each other.

The antenna 150 may transmit the frequency-separated RF output signal RF_OUT to the outside or provide the RF receive signal RF_R, received from the outside, to the duplexer 400 by the duplexer 400. For example, the antenna 150 may include an array antenna, but embodiments are not limited thereto.

For reference, the communication processor 910, the supply modulator 300, the RFIC 200, the power amplifier PA, and the duplexer 400 may be implemented as integrated circuits (ICs), chips, or modules, respectively. In addition, the communication processor 910, the supply modulator 300, the RFIC 200, the power amplifier PA, and the duplexer 400 may be mounted together on a printed circuit board (PCB). However, embodiments are not limited thereto. In one or more embodiments, at least a portion of the communication processor 910, the supply modulator 300, the RFIC 200, the power amplifier PA, and the duplexer 400 may be implemented as a single communication chip.

Furthermore, the wireless communication device 900 illustrated in FIG. 9 may be included in a wireless communication system using a cellular network such as 5G or long-term evolution (LTE), or may be included in a wireless local area network (WLAN) system or another arbitrary wireless communication system. For reference, the configuration of the wireless communication device 900 illustrated in FIG. 9 is only an example. However, embodiments are not limited thereto, and the configuration of the wireless communication device 900 illustrated in FIG. 9 may vary depending on a communication protocol or a communication scheme.

According to one or more embodiments, the communication processor 910 may obtain a reflection coefficient at the receiving frequency based on the reflection coefficients obtained from transmit signals of different transmission frequencies transmitted through the antenna 150.

Furthermore, the communication processor 910 may determine a first receiving tuning code in which a conversion gain Gt of an electrical path (or a tuner 140) connected to the antenna 150 is maximum, among a plurality of tuning codes stored in a look-up table, based on the reflection coefficient at the receiving frequency.

In addition, the communication processor 910 may control the impedance of the antenna 150 based on the first receiving tuning code when receiving a signal at the receiving frequency through the antenna 150.

Thus, the wireless communication device 900 (or the electronic device 100) may improve the reception performance of the antenna 150 using the reflection coefficients measured at the transmission frequency.

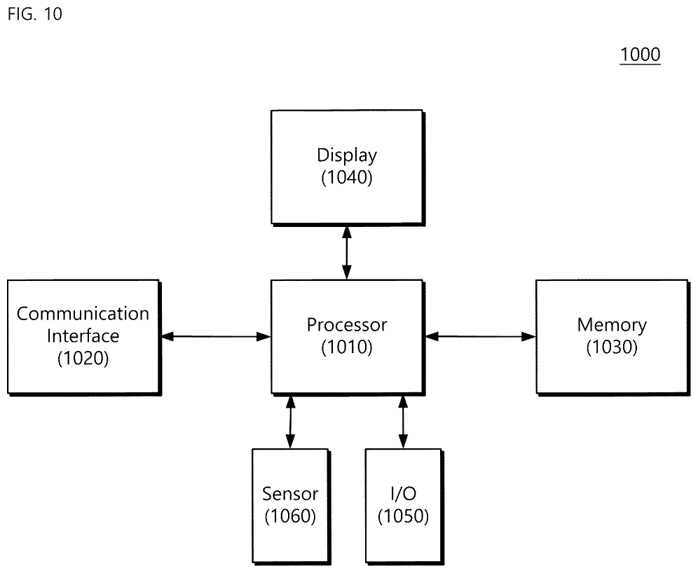

FIG. 10 is a block diagram illustrating an Internet of Things (IoT) device including an electronic device according to one or more embodiments.

Referring to FIG. 10, IT may refer to a network of things or objects that communicate with each other using wired/wireless communication. IoT devices may include devices that have accessible wired or wireless interfaces, communicate with at least one other device through the wired or wireless interfaces, and to transmit or receive data. The accessible interfaces that IoT devices have may include a local area network (LAN), a WLAN such as Wi-Fi, a wireless personal area network (WPAN) such as Bluetooth, a wireless USB, Zigbee, near field communication (NFC), radio-frequency identification (RFID), power line communication (PLC), or a modem communication interface capable of connecting to mobile cellular networks such as 3^{rd} generation (3G), LTE, 4^{th} generation (4G), 5G, etc., The Bluetooth interface may support Bluetooth low energy (BLE).

For example, an IoT device 1000 may include a communication interface 1020 for communicating with an external entity. The communication interface 1020 may be, for example, a wired LAN, Bluetooth, Wi-Fi, a wireless local area communication interface such as Zigbee, or a modem communication interface capable of connecting to PLC or mobile communication networks such as 3G, LTE, 4G, 5G, etc.

It will be understood by one of ordinary skill in the art that the IoT device 1000 according to one or more embodiments has substantially the same configuration as the electronic device 100 illustrated in FIG. 1.

The communication interface 1020 may include a transmitter and/or a receiver. It will be understood by one of ordinary skill in the art that the communication interface 1020 illustrated in FIG. 10 includes at least a portion of the antenna 150 and RFIC 120 illustrated in FIG. 1.

The IoT device 1000 may transmit and/or receive information from an access point or a gateway through a transmitter and/or receiver. In addition, the IoT device 1000 may communicate with a user device or another IoT device to transmit and/or receive control information or data of the IoT device 1000.

The IoT device 1000 may include a processor 1010 performing operations. The processor 1010 illustrated in FIG. 10 may be referred to as having substantially the same configuration as the communication processor 110 illustrated in FIG. 1.

According to one or more embodiments, the processor 1010 may obtain a reflection coefficient at a receiving frequency based on the reflection coefficients obtained from transmitted signals of different transmission frequencies transmitted through the antenna 150.

Furthermore, the processor 1010 may determine a first receiving tuning code in which a conversion gain Gt of an electrical path (or a tuner 140) connected to the antenna 150 is maximum, among a plurality of tuning codes stored in a look-up table, based on the reflection coefficient at the receiving frequency.

In addition, the processor 1010 may control the impedance of the antenna 150 based on the first receiving tuning code when receiving a signal at the receiving frequency through the antenna 150.

Thus, the IoT device 1000 (or the electronic device 100) may improve the receiving performance of the antenna 150 using the reflection coefficients measured at the transmission frequency.

The IoT device 1000 may further include a power supply in which a battery is embedded to supply internal power or which is supplied with external power. In addition, the IoT device 1000 may include a display 1040 to display an internal status or data. A user may control the IoT device 1000 through a user interface (UI) of the display 1040 of the IoT device 1000. The IoT device 1000 may transmit an internal status and/or data to an external entity through the transmitter and receiver control commands and/or data from an external entity through the receiver.

The memory 1030 may store control instruction codes, control data, or user data controlling the IoT device 1000. The memory 1030 may include at least one of a volatile memory or a nonvolatile memory. The nonvolatile memory may include at least one of various memories such as a read-only memory (ROM), a programmable ROM (PROM), an electrically programmable ROM (EPROM), an electrically erasable and programmable ROM (EEPROM), a flash memory, a phase-change random access memory (PRAM), a magnetic RAM (MRAM), a resistive RAM (ReRAM), or a ferroelectric RAM (FRAM). The volatile memory may include at least one of various memories such as a dynamic RAM (DRAM), a static RAM (SRAM), or a synchronous DRAM (SDRAM).

The IoT device 1000 may further include a storage device. The storage device may include at least one of nonvolatile media such as a hard disk drive (HDD), a solid state drive (SSD), an embedded multimedia card (eMMC), or a universal flash storage (UFS). The storage device may store user information, provided through an input/output (I/O) device 1050, and sensing information collected through a sensor 1060.

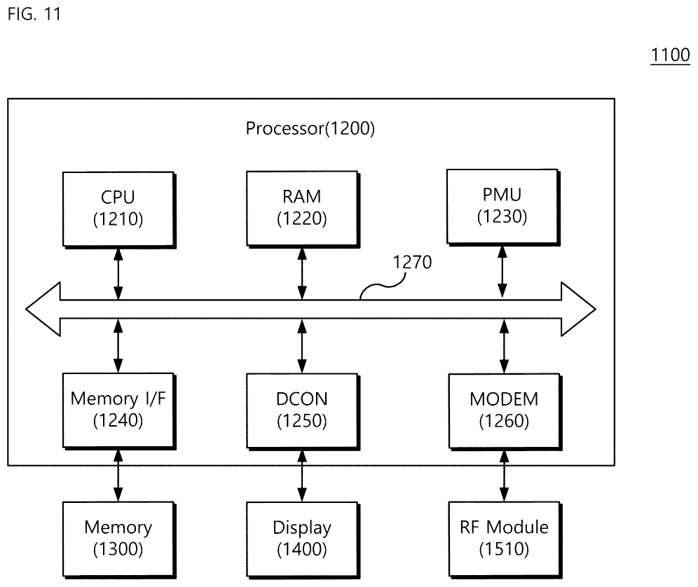

FIG. 11 is a block diagram illustrating a mobile terminal to which an electronic device according to one or more embodiments is applied.

Referring to FIG. 11, a mobile terminal 1100 may include a processor 1200, a memory 1300, a display 1400, and an RF module 1510. The mobile terminal 1100 may further include various components such as a lens, a sensor, or an audio module.

The processor 1200 may be implemented as a system-on-chip (SoC), and may include a CPU 1210, a RAM 1220, a power management unit (PMU) 1230, a memory interface (memory I/F) 1240, a display controller (DCON) 1250, a modem 1260, and a bus 1270. The processor 1200 may further include various intellectual properties (IPs). The processor 1200 may be referred to as ModAP because functions of a modem chip are integrated therein, but example embodiments are not limited thereto.

The CPU 1210 may control the overall operation of the processor 1200 and the mobile terminal 1100. The CPU 1210 may control the operation of each component of the processor 1200. In addition, the CPU 1210 may be implemented as a multi-core processor, which is a computing component having two or more independent cores.

The RAM 1220 may temporarily store programs, data, or instructions. For example, programs and/or data stored in the memory 1300 may be temporarily stored in the RAM 1220 under the control of the CPU 1210 or booting code. The RAM 1220 may be implemented as a DRAM or an SRAM.

The PMU 1230 may manage power of each component of the processor 1200. In addition, the PMU 1230 may determine an operating status of each component of the processor 1200 and control an operation thereof.

The memory interface 1240 may control the overall operation of the memory 1300, and may control data exchange between each component of the processor 1200 and the memory 1300. The memory interface 1240 may write data in the memory 1300 or read data from the memory 1300 depending on a request of the CPU 1210.

The display controller 1250 may transmit display data to be displayed on the display 1400 to the display 1400. The display 1400 may be implemented as a flat panel display, such as a liquid crystal display (LCD) or an organic light emitting diode (OLED), or a flexible display.

For wireless communication, the modem 1260 may modulate data to be transmitted, to be appropriate for a wireless environment, and may recover the received data. The modem 1260 may perform digital communication with the RF module 1510.

The modem 1260 illustrated in FIG. 11 may be referred to as substantially the same component as the communication processor 110 illustrated in FIG. 1.

The RF module 1510 may convert a high-frequency signal, received through the antenna 150, into a low-frequency signal and transmit the converted low-frequency signal to the modem 1260. In addition, the RF module 1510 may convert a low-frequency signal, received from the modem 1260, into a high-frequency signal and transmit the converted high-frequency signal to the outside of the mobile terminal 1100 through the antenna 150. The RF module 1510 may amplify or filter signals.

The RF module 1510 illustrated in FIG. 11 may be referred to as substantially the same component as the RFIC 120 illustrated in FIG. 1.

According to one or more embodiments, the modem 1260 may obtain a reflection coefficient at a receiving frequency based on reflection coefficients obtained from transmit signals having different transmit frequencies transmitted through the antenna 150.

Further, the modem 1260 may determine a first receiving tuning code in which a conversion gain Gt of an electrical path (or the tuner 140) connected to the antenna 150 is maximum, among a plurality of tuning codes stored in a look-up table, based on the reflection coefficient at the receiving frequency.

In addition, the modem 1260 may control impedance of the antenna 150 based on the first receive tuning code when receiving a signal at the receiving frequency through the antenna 150.

Thus, the mobile terminal 1100 (or the electronic device 100) may improve the receive performance of the antenna 150 using the reflection coefficients measured at the transmit frequency.

As described above, the communication processor 110 according to one or more embodiments may obtain a third reflection coefficient G3 for a first receiving frequency RF1 based on reflection coefficients G1 and G2 measured at different transmit frequencies TF1 and TF2.

Furthermore, the communication processor 110 may control the impedance of the antenna 150 based on the third reflection coefficient G3 or the first receive tuning code determined based on the third reflection coefficient G3 when receiving a first receive signal at the first receiving frequency RF1 through the antenna 150.

As a result, the electronic device 100 according to one or more embodiments may improve the receive performance of the antenna 150 using the reflection coefficients measured at different transmit frequencies TF1 and TF2.

As set forth above, an electronic device according to example embodiments may improve the reception performance of an antenna using a reflection coefficient measured at a transmit frequency.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software including one or more instructions that are stored in a storage medium that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

At least one of the devices, units, components, modules, units, or the like represented by a block or an equivalent indication in the above embodiments including, but not limited to, FIGS. 1, 9, 10 and 11, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An electronic device comprising:
an antenna configured to transmit and receive signals within a plurality of frequency bands;
a radio-frequency integrated circuit (RFIC) configured to transmit the signals within the plurality of frequency bands to the antenna;
a coupler configured to transmit at least a portion of signals reflected from the antenna to the RFIC;
a tuner connected to the antenna and the coupler; and
a processor connected to the RFIC and the tuner,
wherein the processor is configured to:
obtain a third reflection coefficient at a first receiving frequency based on a first reflection coefficient at a first transmission frequency and a second reflection coefficient at a second transmission frequency that is greater than the first transmission frequency;
determine, based on the third reflection coefficient, a first receiving tuning code for performing impedance matching to the antenna; and
control impedance of the antenna with the tuner based on the first receiving tuning code.

2. The electronic device of claim 1, wherein the processor is further configured to:
obtain the first reflection coefficient based on a first transmit signal of the first transmission frequency and a first feedback signal reflected from the antenna and transmitted to the RFIC by the coupler as the first transmit signal is transmitted by the antenna; and
obtain the second reflection coefficient based on a second transmit signal of the second transmission frequency and a second feedback signal reflected from the antenna and transmitted to the RFIC by the coupler as the second transmit signal is transmitted by the antenna.

3. The electronic device of claim 2, wherein the processor is further configured to:
determine, based on the third reflection coefficient, the first receiving tuning code in which a conversion gain of an electrical path connected to the antenna is maximum based on a tuning, among a plurality of pre-stored tuning codes, and
wherein the plurality of pre-stored tuning codes are stored in a look-up table.

4. The electronic device of claim 3, wherein the tuner comprises at least one switch and at least one capacitor, and
wherein the processor is further configured to, based on receiving a first receive signal at the first receiving frequency through the antenna, control capacitance of the tuner such that the conversion gain of the electrical path connected to the antenna is maximum, based on the first receiving tuning code.

5. The electronic device of claim 3, wherein the processor is further configured to, based on receiving the first transmit signal or the second transmit signal through the antenna:
determine a transmission tuning code, among the plurality of pre-stored tuning codes, in which the conversion gain of the electrical path connected to the antenna is maximum; and
control the tuner based on the determined transmission tuning code.

6. The electronic device of claim 1, wherein the processor is further configured to:
determine an angle per unit frequency on a complex plane based on a first angle between the first reflection coefficient and the second reflection coefficient represented on the complex plane; and
determine a second angle that the third reflection coefficient has with respect to a real axis on the complex plane, based on the angle per unit frequency.

7. The electronic device of claim 6, wherein the processor is further configured to:
determine a magnitude per unit frequency on the complex plane based on a first magnitude of the first reflection coefficient and a second magnitude of the second reflection coefficient represented on the complex plane; and
determine a third magnitude of the third reflection coefficient represented on the complex plane by multiplying the magnitude per unit frequency by the first receiving frequency.

8. The electronic device of claim 7, wherein the processor is further configured to determine the magnitude per unit frequency on the complex plane by dividing a first value corresponding to a difference between the second magnitude of the second reflection coefficient and the first magnitude of the first reflection coefficient, by a second value corresponding to a difference between the first transmission frequency and the second transmission frequency.

9. The electronic device of claim 6, wherein the processor is further configured to determine an angle between the first reflection coefficient and the second reflection coefficient on the complex plane by multiplying a conjugate complex number of the second reflection coefficient by the first reflection coefficient.

10. The electronic device of claim 1, wherein the first receiving frequency has a value between the first transmission frequency and the second transmission frequency.

11. An antenna tuning method comprising:
determining a first reflection coefficient at a first transmission frequency and a second reflection coefficient at a second transmission frequency that is greater than the first transmission frequency;
obtaining a third reflection coefficient at a first receiving frequency that is different from the first transmission frequency and the second transmission frequency, based on the first reflection coefficient and the second reflection coefficient;
determining, based on the third reflection coefficient, a first receiving tuning code for performing impedance matching to the antenna; and
controlling, with a tuner, impedance of an antenna based on the first receiving tuning code.

12. The antenna tuning method of claim 11, wherein the determining the first reflection coefficient comprises:
transmitting a first transmit signal of the first transmission frequency to the antenna;
obtaining a first feedback signal reflected from the antenna during transmission of the first transmit signal; and
determining the first reflection coefficient based on the first transmit signal and the first feedback signal.

13. The antenna tuning method of claim 12, wherein the obtaining the third reflection coefficient further comprises:
determining a magnitude per unit frequency on a complex plane based on a first magnitude of the first reflection coefficient and a second magnitude of the second reflection coefficient represented on the complex plane; and
determining a third magnitude of the third reflection coefficient represented on the complex plane based on the magnitude per unit frequency.

14. The antenna tuning method of claim 11, wherein the obtaining the third reflection coefficient further comprises:
determining an angle per unit frequency on a complex plane based on a first angle between the first reflection coefficient and the second reflection coefficient represented on the complex plane; and
determining a second angle that the third reflection coefficient has with respect to a real axis on the complex plane, based on the angle per unit frequency.

15. The antenna tuning method of claim 11, wherein the determining the first receiving tuning code comprises:
determining, based on the third reflection coefficient, the first receiving tuning code in which a conversion gain of an electrical path connected to the antenna is maximum, based on a tuning code among a plurality of pre-stored tuning codes, and
wherein the plurality of pre-stored tuning codes are stored in a look-up table.

16. A wireless communication device configured to transmit and receive signals within a plurality of frequency bands, the wireless communication device comprising:
an antenna;
a radio-frequency integrated circuit (RFIC) configured to transmit a signal within a predetermined frequency band to the antenna;
a coupler configured to transmit at least a portion of signals reflected from the antenna to the RFIC;
a tuner connected to the antenna and the coupler; and
a processor connected to the RFIC and the tuner,
wherein the processor is configured to:
obtain a third reflection coefficient at a third frequency band between a first frequency band and a second frequency band that is greater than the first frequency band, based on a first reflection coefficient at a first transmission frequency and a second reflection coefficient at a second transmission frequency;
determine a first receiving tuning code for performing impedance matching to the antenna based on the third reflection coefficient; and
control impedance of the antenna with the tuner based on the first receiving tuning code.

17. The wireless communication device of claim 16, wherein the antenna is configured to:
transmit a first signal within the first frequency band and a second signal within the second frequency band; and
receive a third signal within the third frequency band.

18. The wireless communication device of claim 16, wherein the processor is further configured to:
determine an angle per unit frequency on a complex plane based on a first angle between the first reflection coefficient and the second reflection coefficient represented on the complex plane; and
determine a second angle of the third reflection coefficient with respect to an x-axis on the complex plane based on the angle per unit frequency.

19. The wireless communication device of claim 18, wherein the processor is further configured to:
determine a magnitude per unit frequency on the complex plane based on a first magnitude of the first reflection coefficient and a second magnitude of the second reflection coefficient represented on the complex plane; and
determine a third magnitude of the third reflection coefficient represented on the complex plane based the magnitude per unit frequency.

20. The wireless communication device of claim 16, wherein the processor is further configured to:
determine, based on the third reflection coefficient, the first receiving tuning code in which a conversion gain of an electrical path connected to the antenna is maximum based on a tuning code among a plurality of pre-stored tuning codes, and
wherein the plurality of pre-stored tuning codes are stored in a look-up table.
